(19) United States
(12) Patent Application Publication
(10) Pub. No.: US 2024/0421195 A1
(43) Pub. Date: Dec. 19, 2024

(54) NITRIDE SEMICONDUCTOR DEVICE

(71) Applicant: ROHM CO., LTD., Kyoto-shi (JP)

(72) Inventor: Shinya TAKADO, Kyoto-shi (JP)

(73) Assignee: ROHM CO., LTD., Kyoto-shi (JP)

(21) Appl. No.: 18/740,558

(22) Filed: Jun. 12, 2024

(30) Foreign Application Priority Data
Jun. 15, 2023 (JP) 2023-098655

(51) Int. Cl. H01L 29/20; H01L 29/40; H01L 29/423; H01L 29/778

(52) U.S. Cl. CPC H01L 29/2003; H01L 29/402; H01L 29/4232; H01L 29/7786

(57) ABSTRACT

A nitride semiconductor device includes a passivation layer, which covers a gate layer, and a field plate electrode, which is arranged on the passivation layer. The gate layer includes a gate layer main body and a drain-side extension. The passivation layer includes a first part overlapping both the drain-side extension and the field plate electrode in plan view, a second part continuous with the first part and located between the drain-side extension and the drain opening, and a first step located in a region including a boundary of the first part and the second part. The first part has a first thickness from the upper step surface to an upper surface of the drain-side extension. The second part has a second thickness from the lower step surface to an upper surface of the electron supply layer. The first thickness is greater than the second thickness.

### CROSS-REFERENCE TO RELATED APPLICATION

This application is based upon and claims the benefit of priority from prior Japanese Patent Application No. 2023-098655, filed on Jun. 15, 2023, the entire contents of which are incorporated herein by reference.

### BACKGROUND

### 1. Field

The following description relates to a nitride semiconductor device.

### 2. Description of Related Art

High-electron-mobility transistors (HEMTs) that use nitride semiconductors, such as gallium nitride (GaN), are now being commercialized. Japanese Laid-Open Patent Publication No. 2017-073506 describes one example of a normally-off HEMT using a nitride semiconductor device.

### BRIEF DESCRIPTION OF THE DRAWINGS

FIG. 1 is a schematic plan view of an exemplary nitride semiconductor device in accordance with a first embodiment.

FIG. 2 is an enlarged, schematic plan view illustrating part of the nitride semiconductor device of FIG. 1.

FIG. 3 is a schematic cross-sectional view of the nitride semiconductor device taken along line F3-F3 in FIG. 2.

FIG. 4 is an enlarged, schematic cross-sectional view illustrating part of the nitride semiconductor device of FIG. 3.

FIG. 5 is a schematic cross-sectional view illustrating an exemplary manufacturing step of the nitride semiconductor device illustrated in FIG. 3.

FIG. 6 is a schematic cross-sectional view illustrating an exemplary manufacturing step following the step of FIG. 5.

FIG. 7 is a schematic cross-sectional view illustrating an exemplary manufacturing step following the step of FIG. 6.

FIG. 8 is a schematic cross-sectional view illustrating an exemplary manufacturing step following the step of FIG. 7.

FIG. 9 is a schematic cross-sectional view illustrating an exemplary manufacturing step following the step of FIG. 8.

FIG. 10 is a schematic cross-sectional view illustrating an exemplary manufacturing step following the step of FIG. 9.

FIG. 11 is a schematic cross-sectional view illustrating an exemplary manufacturing step following the step of FIG. 10.

FIG. 12 is a schematic cross-sectional view illustrating an exemplary manufacturing step following the step of FIG. 11.

FIG. 13 is a schematic cross-sectional view of an exemplary nitride semiconductor device in accordance with a second embodiment.

FIG. 14 is a schematic cross-sectional view of an exemplary nitride semiconductor device in accordance with a third embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a semiconductor device will now be described with reference to the accompanying drawings.

Elements in the figures are illustrated for simplicity and clarity and have not necessarily been drawn to scale. In the drawings, characteristic portions may be exaggerated and elements may not be in scale. The accompanying drawings illustrate exemplary embodiments in accordance with the present disclosure and are not intended to limit the present disclosure.

Terms such as “first”, “second”, and “third” in this disclosure are used to distinguish subjects and not used for ordinal purposes. The phrase “at least one of” as used in this disclosure means “one or more” of a desired choice. As one example, the phrase “at least one of” as used in this disclosure means “only one choice” or “both of two choices” in a case where the number of choices is two. As another example, the phrase “at least one of” as used in this disclosure means “only one single choice” or “any combination of two or more choices” if the number of its choices is three or more.

This detailed description includes exemplary embodiments of methods, apparatuses, and/or systems in accordance with the present disclosure. This detailed description is illustrative and is not intended to limit embodiments of the present disclosure or the application and use of the embodiments.

### First Embodiment

### 1. Outline of Nitride Semiconductor Device Structure

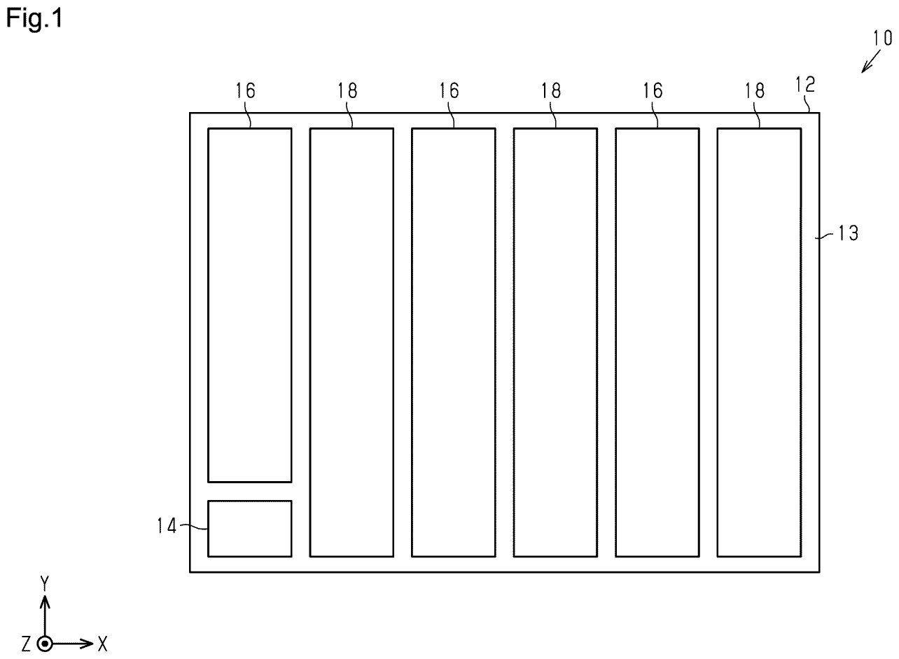

FIG. 1 is a schematic plan view of an exemplary nitride semiconductor device 10 in accordance with a first embodiment. The nitride semiconductor device 10 includes a chip main body 12. FIG. 1 and the other figures indicate X, Y, and Z axes that are orthogonal to one another. The direction of the Z-axis is orthogonal to a main surface (upper surface 13 in FIG. 1) of the chip main body 12. The term “plan view” as used in the present disclosure refers to a view of the nitride semiconductor device 10 taken from above in the Z-axis direction unless otherwise indicated.

The nitride semiconductor device 10 includes at least one gate pad 14, at least one source pad 16, and at least one drain pad 18. For example, the nitride semiconductor device 10 includes a single gate pad 14, multiple source pads 16, and multiple drain pads 18. The gate pad 14, the source pads 16, and the drain pads 18 are formed on the upper surface 13 of the chip main body 12 and may be used as external connection terminals of the nitride semiconductor device 10.

The gate pad 14, the source pads 16, and the drain pads 18 are each, for example, rectangular in plan view. The gate pad 14 is arranged in one corner of the upper surface 13 The source pads 16 and the drain pads 18 extend in the same direction in plan view, more specifically, in the direction of the Y-axis in FIG. 1. The source pads 16 and the drain pads 18 are alternately arranged in the direction of the X-axis, which is orthogonal to the Y-axis direction.

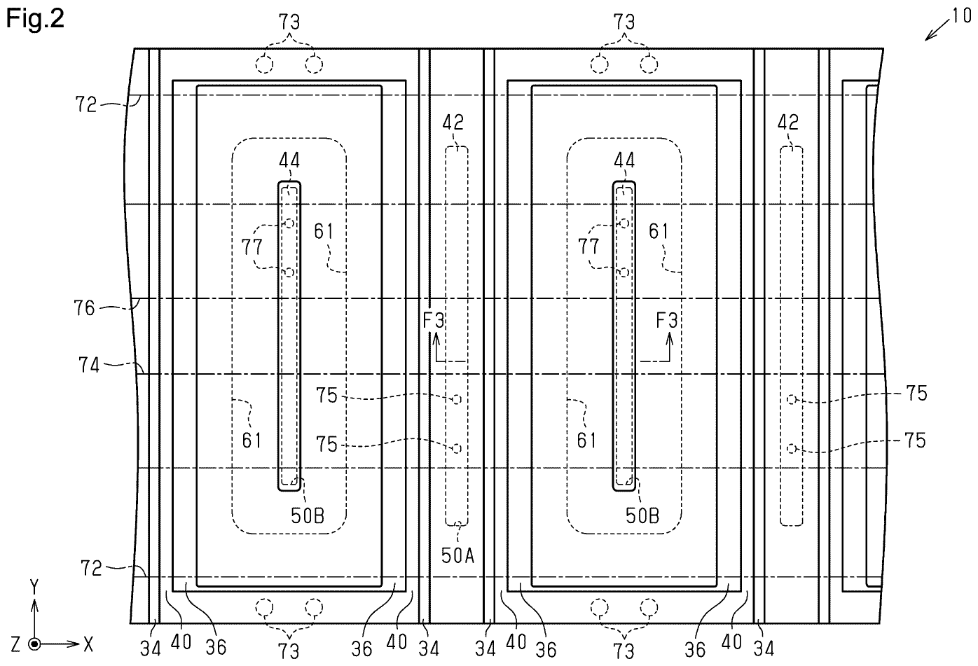

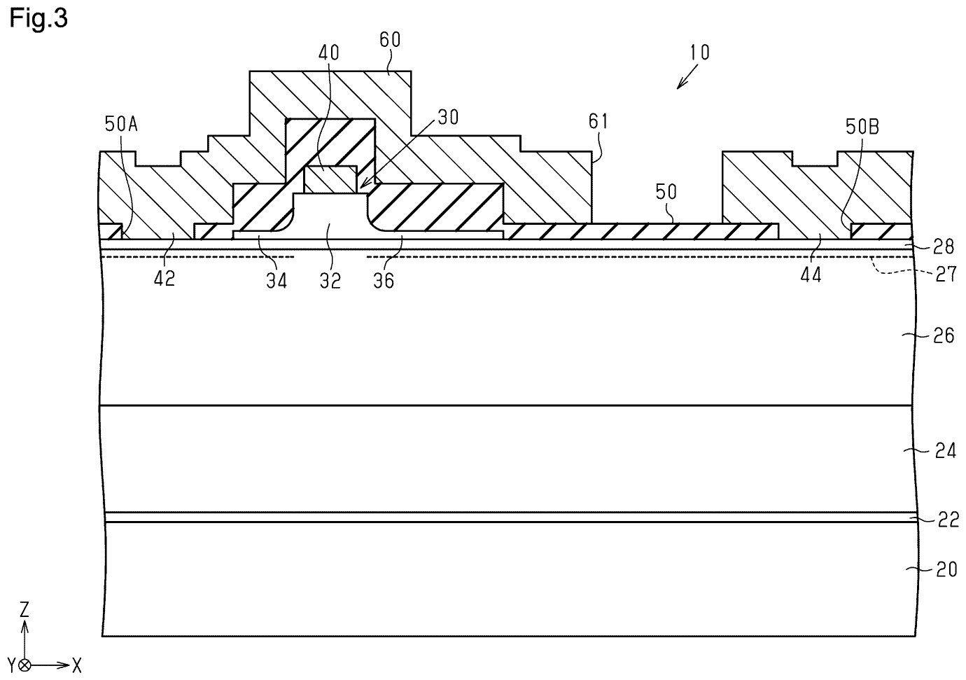

FIG. 2 is an enlarged, schematic plan view illustrating part of the nitride semiconductor device 10 of FIG. 1. FIG. 3 is a schematic cross-sectional view of the nitride semiconductor device 10 taken along line F3-F3 in FIG. 2. The nitride semiconductor device 10 may be a high-electron-mobility transistor (HEMT) that uses a nitride semiconductor.

As illustrated in FIG. 3, the nitride semiconductor device 10 includes a semiconductor substrate 20, a nucleation layer 22 formed on the semiconductor substrate 20, a buffer layer 24 formed on the nucleation layer 22, an electron transit layer 26 formed on the buffer layer 24, and an electron supply layer 28 formed on the electron transit layer 26.

The semiconductor substrate 20 may be formed from silicon (Si), silicon carbide (SiC), gallium nitride (GaN), sapphire, or other substrate materials. For example, the semiconductor substrate 20 may be a Si substrate. The semiconductor substrate 20 may have a thickness of, for example, 200 μm or greater and 1500 μm or less. The Z-axis direction corresponds to the thickness-wise direction of the semiconductor substrate 20.

The nucleation layer 22 is formed from a nitride semiconductor. For example, the nucleation layer 22 may be an aluminum nitride (AlN) layer having a thickness of 100 nm or greater and 500 nm or less. The nucleation layer 22 may be the lowermost layer of the buffer layer 24.

The buffer layer 24 may be formed from any material that reduces wafer warping and cracking that would be caused by the difference in coefficient of thermal expansion between the semiconductor substrate 20 and the electron transit layer 26. The buffer layer 24 may include one or more nitride semiconductor layers. The buffer layer 24 includes, for example, at least one of an AlN layer, an aluminum gallium nitride (AlGaN) layer, and a graded AlGaN layer having different aluminum (Al) compositions. For example, the buffer layer 24 may include a single AlN layer, a single AlGaN layer, a layer having an AlGaN/GaN superlattice structure, a layer having an AlN/AlGaN superlattice structure, or a layer having an AlN/GaN superlattice structure.

The electron transit layer 26 is formed from a nitride semiconductor. The electron transit layer 26 may be, for example, a GaN layer. The electron transit layer 26 may have a thickness of, for example, 0.1 μm or greater and 2 μm or less. The electron transit layer 26 may include one or more nitride semiconductor layers. To reduce leakage current in the electron transit layer 26, part of the electron transit layer 26 may include an impurity so that regions other than the outermost part of the electron transit layer 26 are semi-insulative. In this case, the impurity is, for example, carbon (C). The concentration of the impurity may be, for example, greater than or equal to 1×10¹⁹cm⁻³ at a peak concentration. GaN is one example of a first nitride semiconductor.

The electron supply layer 28 is formed from a nitride semiconductor having a larger bandgap than the electron transit layer 26. The electron supply layer 28 may be, for example, an AlGaN layer. The band gap becomes larger as the Al composition increases. Thus, the electron supply layer 28, which is an AlGaN layer, has a larger band gap than the electron transit layer 26, which is a GaN layer. In one example, the electron supply layer 28 is formed from AlₓGa₁₋ₓN, where x is 0.1<x<0.4, and more preferably, 0.1<x<0.3. The electron supply layer 28 may have a thickness of, for example, 5 nm or greater and 20 nm or less. AlGaN is one example of a second nitride semiconductor.

The electron transit layer 26 and the electron supply layer 28 have bulk regions of different lattice constants. Thus, the nitride semiconductor (e.g., GaN) of the electron transit layer 26 and the nitride semiconductor (e.g., AlGaN) of the electron supply layer 28 form a lattice-mismatched heterojunction. The spontaneous polarization of the electron transit layer 26 and the electron supply layer 28 and the piezoelectric polarization resulting from the compression stress received by the heterojunction of the electron transit layer 26 cause the energy level of the conduction band of the electron transit layer 26 to be lower than the Fermi level in the proximity of the heterojunction interface between the electron transit layer 26 and the electron supply layer 28. Thus, a two-dimensional electron gas (2DEG) 27 forms in the electron transit layer 26 at a position proximate to (e.g., distanced by approximately a few nanometers from interface) the heterojunction interface of the electron transit layer 26 and the electron supply layer 28.

The nitride semiconductor device 10 further includes a gate layer 30, which is formed on part of the electron supply layer 28, and a gate electrode 40, which is formed on the gate layer 30.

The gate layer 30 is formed from a nitride semiconductor. For example, the gate layer 30 is formed from a nitride semiconductor having a smaller band gap than the electron supply layer 28 and containing an acceptor impurity. In one example, the gate layer 30 is a GaN layer (p-type GaN layer) doped with an acceptor impurity. The acceptor impurity may contain at least one of magnesium (Mg), zinc (Zn), and carbon (C). The maximum concentration of the acceptor impurity in the gate layer 30 is, for example, 7×10¹⁸ cm⁻³ or greater and 1×10²⁰ cm⁻³ or less.

The gate electrode 40 includes one or more metal layers. For example, the gate electrode 40 may be a titanium nitride (TiN) layer. Alternatively, the gate electrode 40 may be formed by a first metal layer of Ti and a second metal layer of TiN formed on the first metal layer. The gate electrode 40 and the gate layer 30 may form a Schottky junction. The gate electrode 40 may have a thickness of, for example, 50 nm or greater and 200 nm or less.

The nitride semiconductor device 10 further includes a passivation layer 50. The passivation layer 50 covers the electron supply layer 28, the gate layer 30, and the gate electrode 40. The passivation layer 50 may be formed from a material containing one of, for example, silicon dioxide (SiO₂), silicon nitride (SiN), silicon oxynitride (SiON), alumina (Al₂O₃), AlN, and aluminum oxynitride (AlON). The passivation layer 50 may have a thickness of, for example, 50 nm or greater and 200 nm or less. The passivation layer 50 includes a source opening 50A and a drain opening 50B, each of which partially exposes the upper surface of the electron supply layer 28.

The nitride semiconductor device 10 further includes a source electrode 42, which contacts the electron supply layer 28 through the source opening 50A of the passivation layer 50, and a drain electrode 44, which contacts the electron supply layer 28 through the drain opening 50B of the passivation layer 50.

The source electrode 42 and the drain electrode 44 each include one or more metal layers. For example, the source electrode 42 and the drain electrode 44 may be formed from one or any combination of a Ti layer, a TiN layer, an Al layer, an aluminum-silicon-copper (AlSiCu) layer, and an aluminum-copper (AlCu) layer. The source opening 50A is filled with at least part of the source electrode 42, which is in ohmic contact with the 2DEG 27 underneath the electron supply layer 28 through the source opening 50A. In the same manner, the drain opening 50B is filled with at least part of the drain electrode 44, which is in ohmic contact with the 2DEG 27 underneath the electron supply layer 28 through the drain opening 50B. Although not illustrated in the drawings, the semiconductor substrate 20 is electrically connected to the source electrode 42, and voltage, having the same potential as that at the source electrode 42, is applied to the semiconductor substrate 20.

When the gate layer 30 is formed from a nitride semiconductor containing an acceptor impurity, at zero-bias where no voltage is applied to the gate electrode 40, the 2DEG 27 in the region underneath the gate layer 30 is depleted to interrupt a conductive path (channel). Thus, the HEMT is of a normally-off type of which the threshold voltage is a positive value.

### 2. Exemplary Structure of Gate Layer

As illustrated in FIG. 3, the gate layer 30 is located between the source opening 50A and the drain opening 50B in the X-axis direction. The gate layer 30 is separated from both the source opening 50A and the drain opening 50B and located closer to the source opening 50A than the drain opening 50B.

The gate layer 30 includes a gate layer main body 32, which includes the upper surface of the gate layer 30, and a source-side extension 34 and a drain-side extension 36, which are thinner than the gate layer main body 32. The gate layer main body 32, the source-side extension 34, and the drain-side extension 36 are each in contact with the electron supply layer 28. The source-side extension 34 and the drain-side extension 36 results in the lower surface of the gate layer 30 having a larger area than the upper surface of the gate layer 30.

The gate layer main body 32 is formed integrally with the source-side extension 34 and the drain-side extension 36. For example, the gate layer main body 32 has a ridge-shaped cross section (rectangular cross section). The gate layer main body 32 is not limited to any particular cross-sectional shape and may have a trapezoidal cross section or any other cross-sectional shape. The gate layer main body 32 may have a thickness determined in accordance with various parameters including the gate threshold voltage. The thickness of the gate layer main body 32 may be, for example, 80 nm or greater and 150 nm or less.

The source-side extension 34 extends from the gate layer main body 32 toward the source opening 50A. Part of the passivation layer 50 extends between the source electrode 42, which is embedded in the source opening 50A, and the source-side extension 34. The drain-side extension 36 extends from the gate layer main body 32 toward the drain opening 50B. Part of the passivation layer 50 extends between the drain electrode 44, which is embedded in the drain opening 50B, and the drain-side extension 36. The source-side extension 34 and the drain-side extension 36 may each have a thickness that is, for example, less than or equal to one half the thickness of the gate layer main body 32.

The drain-side extension 36 may have a greater dimension in the X-axis direction than the source-side extension 34. The X-axis direction dimension (length) of the source-side extension 34 may be, for example, 0.2 μm or greater and 0.3 μm or less. The X-axis direction dimension (length) of the drain-side extension 36 may be, for example, 0.2 μm or greater and 0.6 μm or less.

The source-side extension 34 and the drain-side extension 36 may each include a flat portion having a substantially uniform thickness. The thickness of the flat portion of the source-side extension 34 and the thickness of the flat portion of the drain-side extension 36 may be, for example, 5 nm or greater and 25 nm or less. In this specification, “substantially uniform thickness” refers to a thickness being within a manufacturing tolerance range (e.g., 20%). Further, as illustrated in FIG. 3, the source-side extension 34 and the drain-side extension 36 may each include an intermediate portion between the flat portion and the gate layer main body 32, and the intermediate portion may be thicker than the flat portion. In one example, the thickness of the intermediate portion gradually decreases as the gate layer main body 32 becomes farther.

### 3. Exemplary Structure of Field Plate Electrode

As illustrated in FIG. 3, the nitride semiconductor device 10 further includes a field plate electrode 60 arranged on the passivation layer 50 and electrically connected to the source electrode 42. In the example of FIG. 3, the field plate electrode 60 is formed integrally with the source electrode 42 and acts as part of the source electrode 42. Accordingly, voltage having the same potential as that at the field plate electrode 60 is applied to the source electrode 42. The field plate electrode 60 is also referred to as a source field plate. The field plate electrode 60 covers the gate layer 30 entirely in plan view.

The field plate electrode 60 is separate from the drain electrode 44. The field plate electrode 60 includes an end 61 located between the gate layer 30 (drain-side extension 36) and the drain electrode 44 (drain opening 50B) in plan view. The field plate electrode 60 serves to mitigate electric field concentration at the vicinity of the end of the gate electrode 40 and the vicinity of the end of the gate layer 30 when a drain voltage is applied to the drain electrode 44 in the zero bias state, in which no gate input voltage is applied to the gate electrode 40.

### 4. Exemplary Planar Layout of Nitride Semiconductor Device

With reference to FIG. 2, an exemplary planar layout of the HEMT structure (nitride semiconductor device 10) will now be described. In FIG. 2, the passivation layer 50 is not illustrated to aid understanding. Further, the source opening 50A, the drain opening 50B, and the field plate electrode 60 are illustrated in broken lines.

As illustrated in FIG. 2, the nitride semiconductor device 10 includes gate wiring 72, source wiring 74, and drain wiring 76. The gate wiring 72, the source wiring 74, and the drain wiring 76 are formed on an interlayer insulative layer (not illustrated) covering the source electrode 42 and the drain electrode 44. For example, the gate wiring 72 is connected to the gate electrode 40 by gate connection conductors 73, which extend through the interlayer insulative layer to the gate electrode 40. The source wiring 74 is connected to the source electrode 42 by source connection conductors 75, which extend through the interlayer insulative layer. The drain wiring 76 is connected to the drain electrode 44 by drain connection conductors 77, which extend through the interlayer insulative layer.

The nitride semiconductor device 10 includes, in an element region, transistor elements that each have a HEMT structure. Although FIG. 2 illustrates transistor elements arranged next to one another in the X-axis direction, transistor elements are actually arranged in the X-axis direction and the Y-axis direction.

The drain electrode 44, which is provided for each transistor element, extends in the Y-axis direction in plan view. The source electrode 42 is, for example, arranged so as to surround each drain electrode 44 in plan view. As described with reference to FIG. 3, the source electrode 42 includes the field plate electrode 60. That is, the field plate electrode 60 is formed integrally with the source electrode 42 and extends toward the drain electrode 44 that is adjacent in plan view. In the example of FIG. 2, the source electrode 42 is formed continuously in the X-axis direction over the transistor elements that are adjacent to one another in the X-axis direction but may instead be separated into a number of portions in the X-axis direction.

The gate layer 30 and the gate electrode 40 are provided for each transistor element. Each gate layer 30 and each gate electrode 40 has a closed shape and surrounds one of the drain electrodes 44 in plan view.

### 5. Exemplary Structure of Passivation Layer

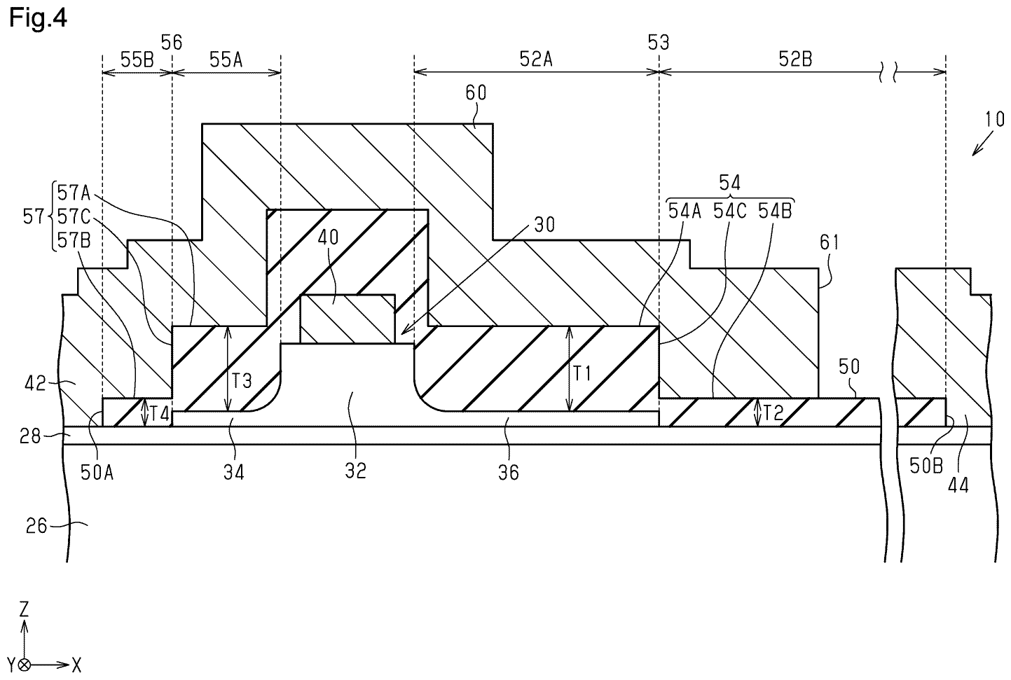

With reference to FIGS. 3 and 4, an exemplary structure of the passivation layer 50 will now be described. FIG. 4 is an enlarged, schematic cross-sectional view illustrating part of the nitride semiconductor device 10 of FIG. 3.

As illustrated in FIG. 4, the passivation layer 50 includes a first part 52A overlapping both the drain-side extension 36 of the gate layer 30 and the field plate electrode 60 in plan view. Further, the passivation layer 50 includes a second part 52B that is continuous with the first part 52A and located between the drain-side extension 36 and the drain opening 50B. The passivation layer 50 also includes a first step 54 located in a region including a boundary 53 of the first part 52A and the second part 52B. The first step 54 includes an upper step surface 54A, a lower step surface 54B that is lower than the upper step surface 54A, and a step wall 54C that connects the upper step surface 54A and the lower step surface 54B.

The first part 52A has a first thickness T1 from the upper step surface 54A to the upper surface of the drain-side extension 36. The second part 52B has a second thickness T2 from the lower step surface 54B to the upper surface of the electron supply layer 28. The passivation layer 50 is formed so that the first thickness T1 is greater than the second thickness T2. The second thickness T2 may be, for example, 50 nm or greater and 150 nm or less, and is 100 nm in the first embodiment. The first thickness T1 may be, for example, 100 nm or greater and 200 nm or less, and is 150 nm in the first embodiment. The ratio of the first thickness T1 to the second thickness T2, or T1/T2, is, for example, greater than 1 and less than or equal to 3.

The first part 52A is dominated by the region having the first thickness T1. In the example of FIG. 4, the region of the first thickness T1 corresponds to the entire or substantially the entire first part 52A. Further, the second part 52B is dominated by the region having the second thickness T2. In the example of FIG. 4, the region of the second thickness T2 corresponds to the entire or substantially the entire second part 52B.

The first part 52A is formed so that the first thickness T1 is greater than the thickness of the drain-side extension 36. In the example of FIG. 4, the total thickness of the first thickness T1 and the thickness of the drain-side extension 36 is greater than the thickness of the gate layer main body 32 and less than the total thickness of the thickness of the gate layer main body 32 and the thickness of the gate electrode 40.

The passivation layer 50 further includes a third part 55A overlapping both the source-side extension 34 of the gate layer 30 and the field plate electrode 60 in plan view. Further, the passivation layer 50 includes a fourth part 55B that is continuous with the third part 55A and located between the source-side extension 34 and the source opening 50A. The passivation layer 50 also includes a second step 57 located in a region including a boundary 56 of the third part 55A and the fourth part 55B. The second step 57 includes an upper step surface 57A, a lower step surface 57B that is lower than the upper step surface 57A, and a step wall 57C that connects the upper step surface 57A and the lower step surface 57B.

The third part 55A has a third thickness T3 from the upper step surface 57A to the upper surface of the source-side extension 34. The fourth part 55B has a fourth thickness T4 from the lower step surface 57B to the upper surface of the electron supply layer 28. The passivation layer 50 is formed so that the third thickness T3 is greater than the fourth thickness T4. The fourth thickness T4 may be, for example, 50 nm or greater and 150 nm or less, and is 100 nm in the first embodiment. The third thickness T3 may be, for example, 100 nm or greater and 200 nm or less, and is 150 nm in the first embodiment. The ratio of the third thickness T3 to the fourth thickness T4, or T3/T4, is for example, greater than 1 and less than or equal to 3.

The third part 55A is dominated by the region having the third thickness T3. In the example of FIG. 4, the region of the third thickness T3 corresponds to the entire or substantially the entire third part 55A. Further, the fourth part 55B is dominated by the region having the fourth thickness T4. In the example of FIG. 4, the region of the fourth thickness T4 corresponds to the entire or substantially the entire fourth part 55B.

The third part 55A is formed so that the third thickness T3 is greater than the thickness of the source-side extension 34. In the example of FIG. 4, the total thickness of the third thickness T3 and the thickness of the source-side extension 34 is greater than the thickness of the gate layer main body 32 and less than the total thickness of the thickness of the gate layer main body 32 and the thickness of the gate electrode 40.

### 6. Exemplary Method for Manufacturing Nitride Semiconductor Device

An exemplary method for manufacturing the nitride semiconductor device 10 will now be described.

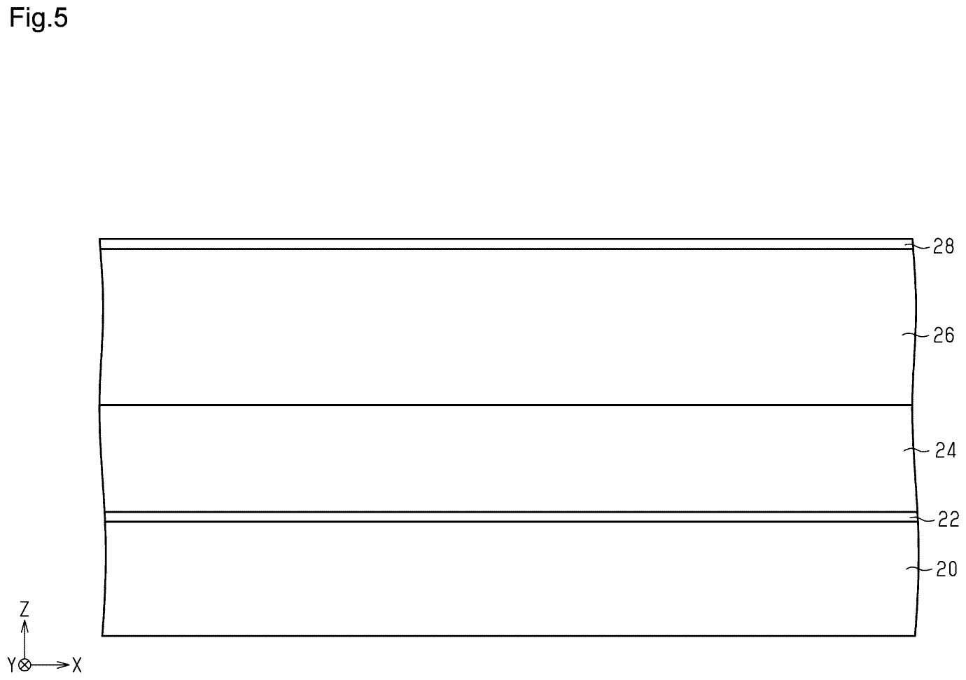

FIGS. 5 to 12 are schematic cross-sectional views illustrating manufacturing steps of the nitride semiconductor device 10. In FIGS. 5 to 12, to aid understanding, members including or corresponding to the final elements of the nitride semiconductor device 10 are indicated by the same reference characters as the final elements.

As illustrated in FIG. 5, the nucleation layer 22, the buffer layer 24, the electron transit layer 26, and the electron supply layer 28 are formed through epitaxial growth on the semiconductor substrate 20, which is, for example, a Si substrate. The epitaxial growth process may be, for example, Metal Organic Chemical Vapor Deposition (MOCVD).

The nucleation layer 22, the buffer layer 24, the electron transit layer 26, and the electron supply layer 28 may each be formed by any one of the corresponding nitride semiconductor layers described above with reference to FIG. 3. In the first embodiment, for example, the nucleation layer 22 is an AlN layer, the buffer layer 24 is a grated AlGaN layer, the electron transit layer 26 is a GaN layer, and the electron supply layer 28 is an AlGaN layer.

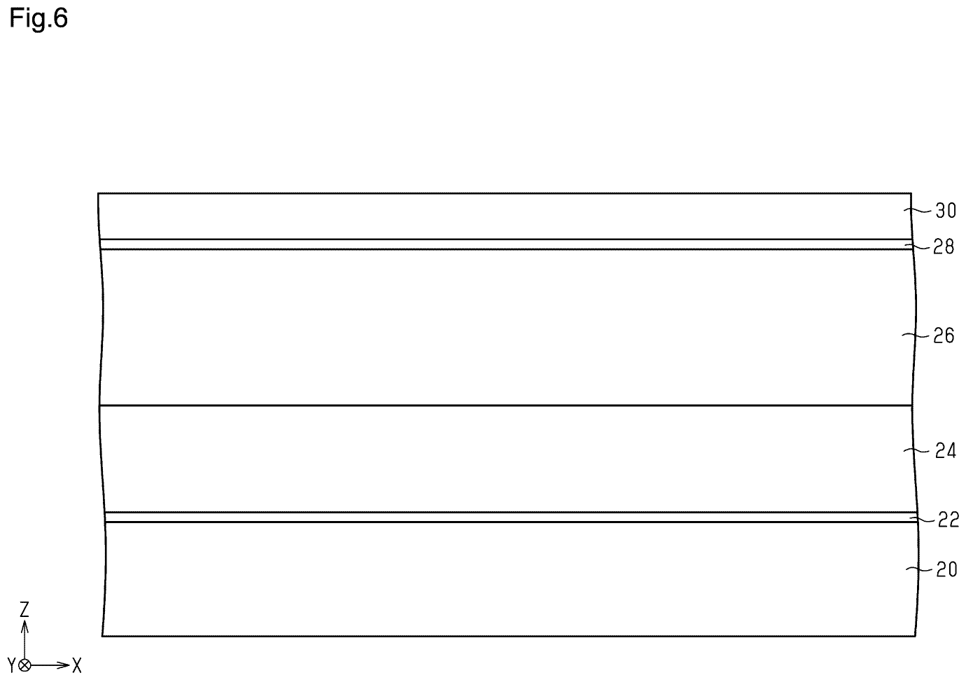

Then, as illustrated in FIG. 6, the nitride semiconductor layer corresponding to the gate layer 30 is formed on the electron supply layer 28 through epitaxial growth. In the first embodiment, the nitride semiconductor layer corresponding to the gate layer 30 is, for example, a p-type GaN layer doped with Mg, which is an acceptor impurity.

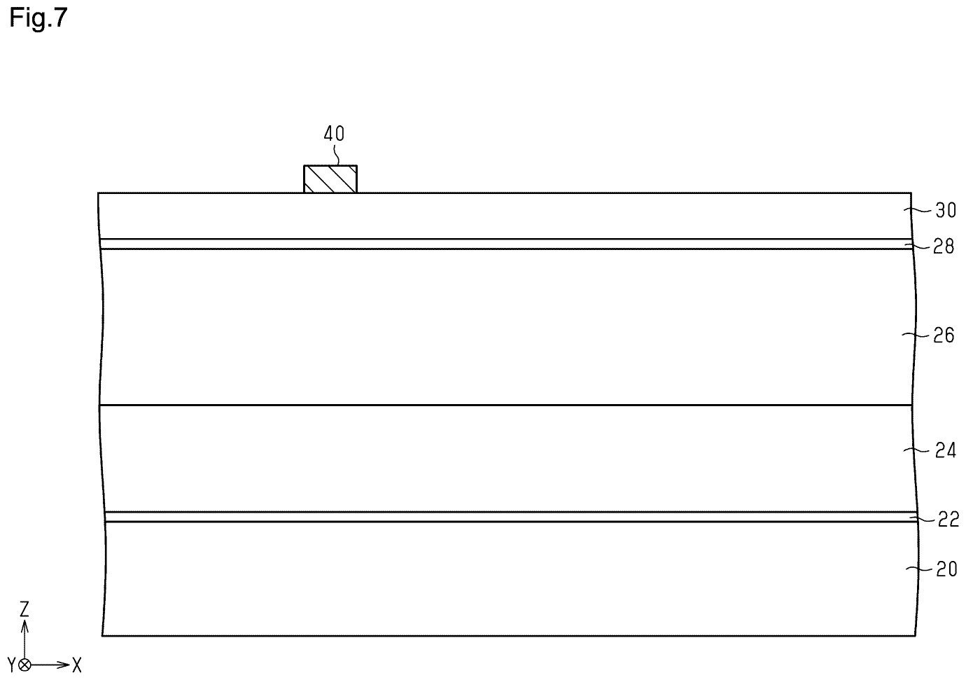

Then, as illustrated in FIG. 7, the gate electrode 40 is formed on the nitride semiconductor layer corresponding to the gate layer 30. The gate electrode 40 may be formed by, for example, forming an electrode layer (not illustrated) through a sputtering process and then selectively etching the electrode layer using a mask (not illustrated). In the first embodiment, the gate electrode 40 is, for example, a TiN layer.

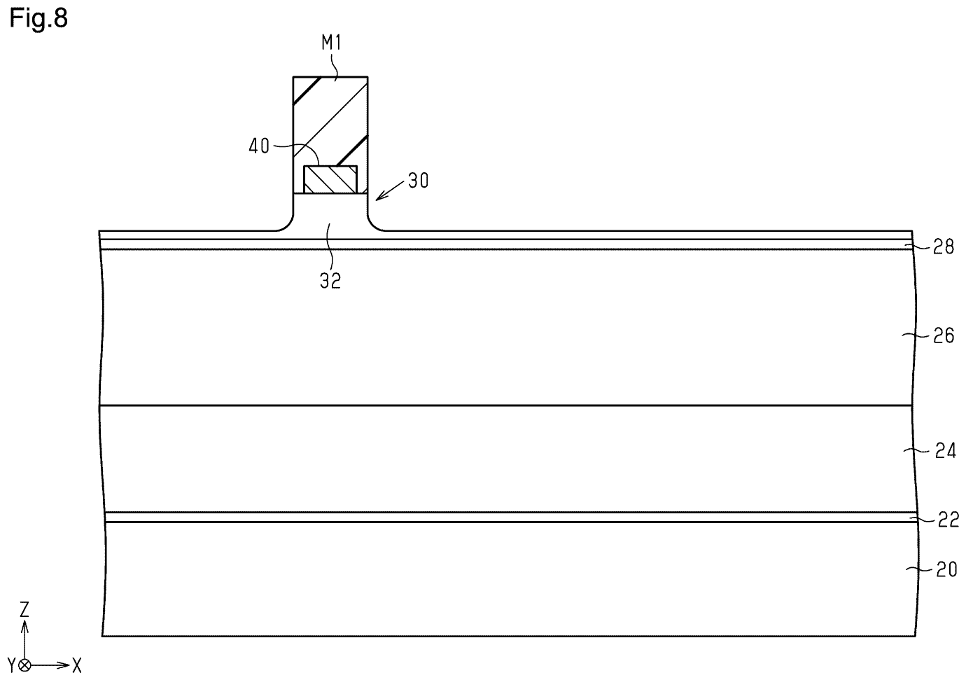

Then, as illustrated in FIG. 8, the nitride semiconductor layer of FIG. 7 corresponding to the gate layer 30 is selectively etched using a mask M1 to form the gate layer main body 32. As described above, the cross-sectional shape of the gate layer main body 32 is not particularly limited. After the gate layer main body 32 is formed, the mask M1 is removed.

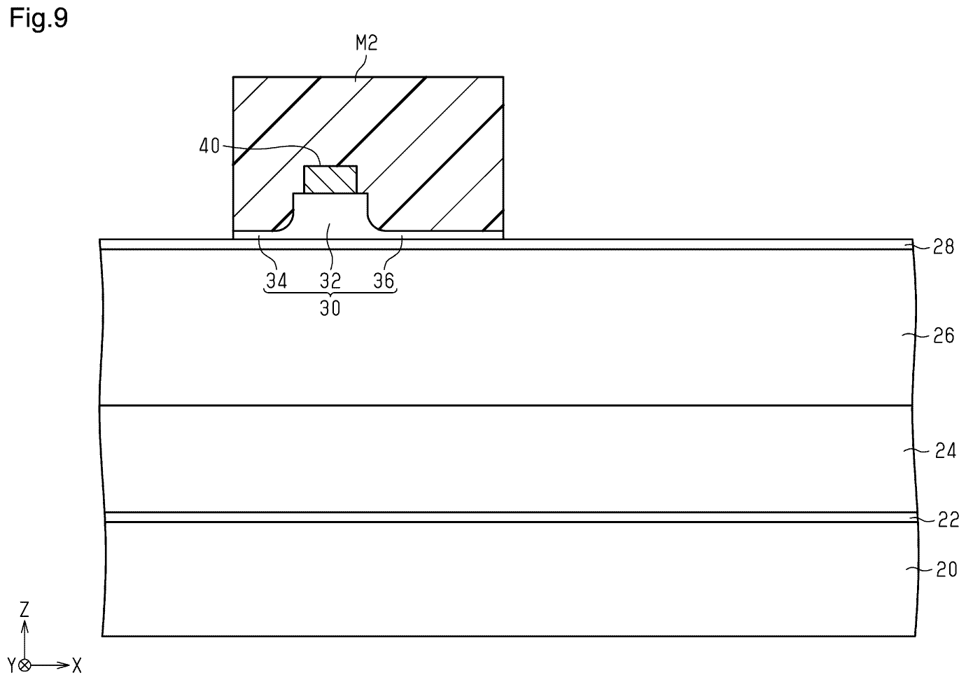

Then, as illustrated in FIG. 9, the nitride semiconductor layer of FIG. 8 corresponding to the gate layer 30 is selectively etched using a mask M2 to form the source-side extension 34 and the drain-side extension 36. This forms the gate layer 30, which includes the gate layer main body 32, the source-side extension 34, and the drain-side extension 36. After the gate layer 30 of FIG. 9 is formed, the mask M2 is removed.

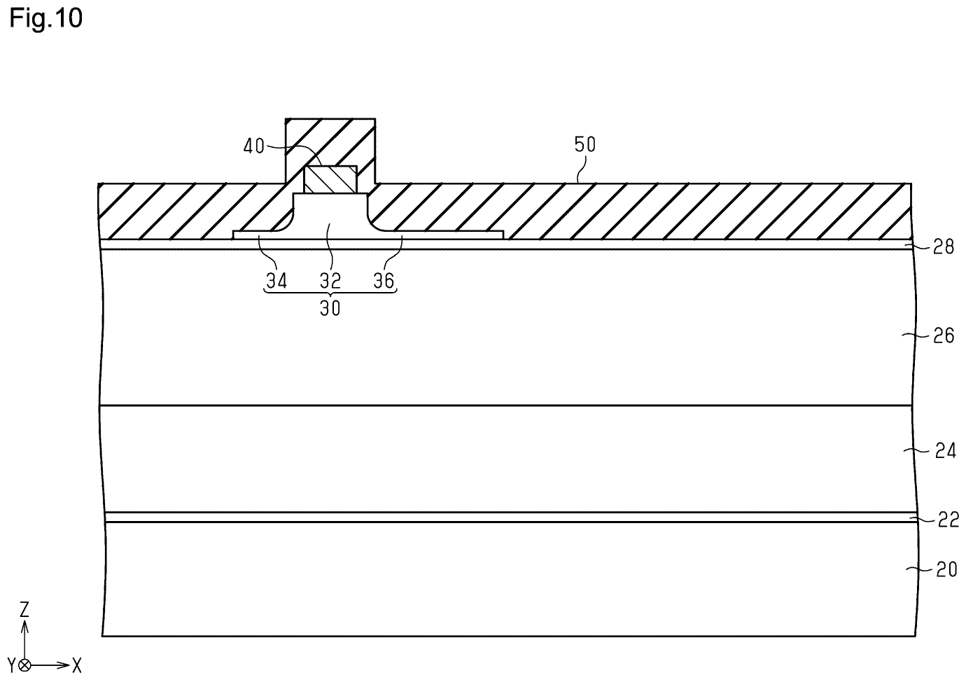

Then, as illustrated in FIG. 10, an insulation layer corresponding to the passivation layer 50 is formed. The insulation layer is formed so that the passivation layer 50 on the drain-side extension 36 has the first thickness T1 (refer to FIG. 4) and so that the passivation layer 50 on the source-side extension 34 has the third thickness T3 (refer to FIG. 4). In the first embodiment, the passivation layer 50 is, for example, a SiN layer.

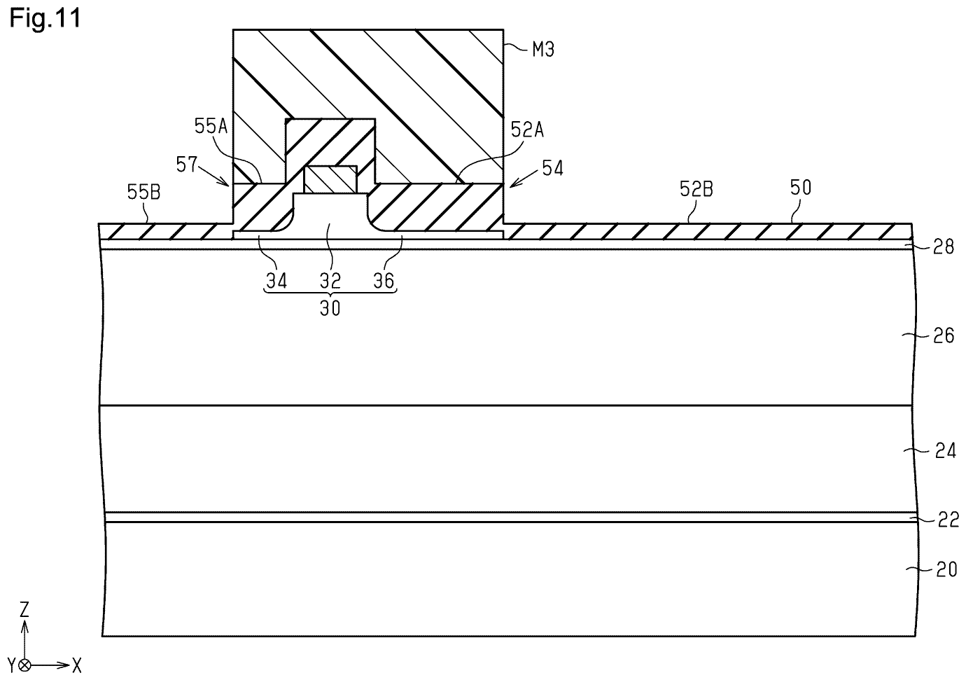

Then, as illustrated in FIG. 11, the insulation layer of FIG. 10 corresponding to the passivation layer 50 is selectively etched using a mask M3 to form the first part 52A and the second part 52B with the first step 54 located in between, and the third part 55A and the fourth part 55B with the second step 57 located in between. Then, the mask M3 is removed. In the step of FIG. 11, etching is performed so that the second part 52B has the second thickness T2 (refer to FIG. 4) and so that the fourth part 55B has the fourth thickness T4 (refer to FIG. 4).

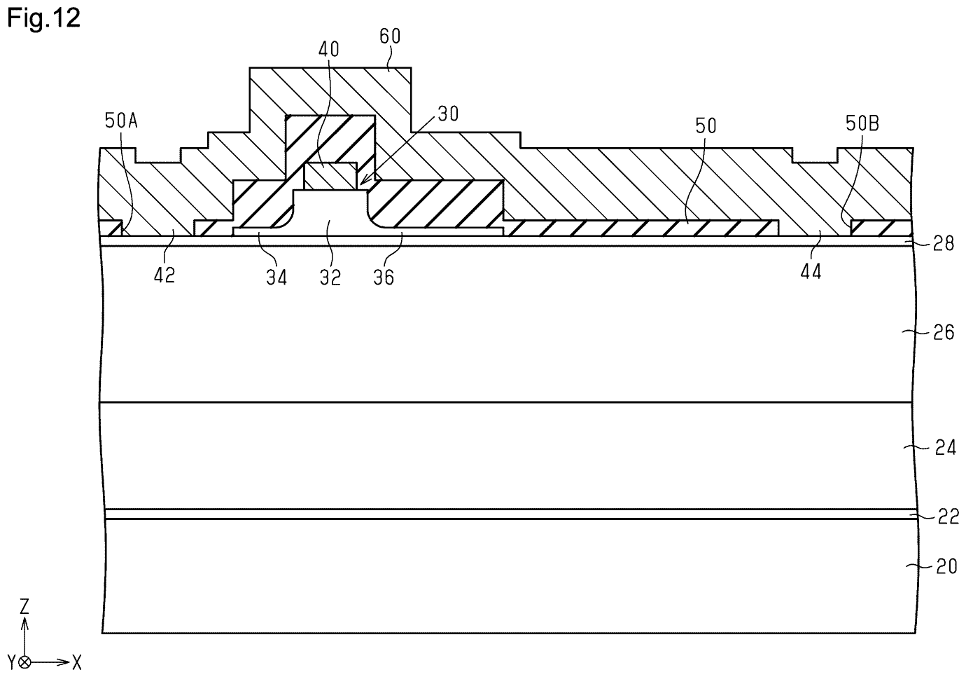

Then, as illustrated in FIG. 12, the source opening 50A and the drain opening 50B are formed in the passivation layer 50. Further, an electrode layer including the source electrode 42, which also includes the field plate electrode 60 in the first embodiment, and the drain electrode 44 is formed through, for example, a sputtering process. Afterward, the electrode layer of FIG. 12 is selectively etched using a mask (not illustrated) to form the source electrode 42 and the drain electrode 44 as illustrated in FIG. 3.

### 7. Operation of Nitride Semiconductor Device

The nitride semiconductor device 10 includes the field plate electrode 60 that covers the upper side of the gate layer 30 to mitigate the electric field locally applied to the end of the gate layer 30. In the first embodiment, the field plate electrode 60 is formed integrally with the source electrode 42. Accordingly, the source potential is applied to the field plate electrode 60. In this structure, the field plate electrode 60 mitigates the concentration of the electric field at the end of the gate layer 30.

A structure that has a field plate electrode arranged above a gate layer will typically have a greater source-gate capacitance than a structure that does not have a field plate structure. In this respect, the structure of the present disclosure has the passivation layer 50. In the first embodiment, the passivation layer 50 includes the first part 52A, the second part 52B, and the first step 54. The first part 52A of the passivation layer 50 overlaps both the drain-side extension 36 of the gate layer 30 and the field plate electrode 60 in plan view. The second part 52B of the passivation layer 50 is continuous with the first part 52A and located between the drain-side extension 36 and the drain opening 50B. The first step 54 is the part of the passivation layer 50 located at a region including the boundary 53 of the first part 52A and the second part 52B.

In such a structure, the effect of the field plate electrode 60 mitigating electric field concentration at the end of the drain-side extension 36 is dependent on the thickness of the passivation layer 50 and, in particular, becomes more pronounced as the second part 52B becomes thinner. Thus, the effect mitigating electric field concentration at the end of the drain-side extension 36 is mainly dependent on the thickness of the second part 52B rather than the first part 52A. The passivation layer 50 is formed so that the first thickness T1 of the first part 52A is greater than the second thickness T2 of the second part 52B. This structure reduces the source-gate capacitance formed through the first part 52A between the field plate electrode 60 and the drain-side extension 36 (gate layer 30) and effectively mitigates electric field concentration at the end of the drain-side extension 36.

Further, the passivation layer 50 includes the third part 55A, the fourth part 55B, and the second step 57. The third part 55A of the passivation layer 50 overlaps both the source-side extension 34 of the gate layer 30 and the field plate electrode 60 in plan view. The fourth part 55B of the passivation layer 50 is continuous with the third part 55A and located between the source-side extension 34 and the source opening 50A. The second step 57 is the part of the passivation layer 50 located at a region including the boundary 56 of the third part 55A and the fourth part 55B.

The effect of the field plate electrode 60 mitigating electric field concentration at the end of the source-side extension 34 is dependent on the thickness of the passivation layer 50 and, in particular, becomes more pronounced as the fourth part 55B becomes thinner. Thus, the effect mitigating electric field concentration at the end of the source-side extension 34 is mainly dependent on the fourth part 55B rather than the third part 55A. The passivation layer 50 is formed so that the third thickness T3 of the third part 55A is greater than the fourth thickness T4 of the fourth part 55B. This structure reduces source-gate capacitance formed through the third part 55A between the field plate electrode 60 and the source-side extension 34 (gate layer 30) and effectively mitigates electric field concentration at the end of the source-side extension 34.

The nitride semiconductor device 10 of the first embodiment has the advantages described below.

(1-1) The passivation layer 50 includes the first part 52A, which is formed on the drain-side extension 36 and has the first thickness T1, and the second part 52B, which is formed on the electron supply layer 28 and has the second thickness T2. The passivation layer 50 is formed so that the first thickness T1 of the first part 52A is greater than the second thickness T2 of the second part 52B. This structure reduces the source-gate capacitance and effectively mitigates electric field concentration at the end of the drain-side extension 36.

(1-2) The ratio of the first thickness T1 to the second thickness T2 is greater than 1 and less than or equal to 3. This structure reduces the source-gate capacitance and further effectively mitigates electric field concentration at the end of the drain-side extension 36.

(1-3) Further, the first part 52A is dominated by the region having the first thickness T1, and the second part 52B is dominated by the region having the second thickness T2. This structure reduces the source-gate capacitance and further effectively mitigates electric field concentration at the end of the drain-side extension 36.

(1-4) The first thickness T1 is 100 nm or greater and 200 nm or less. This structure effectively reduces the source-gate capacitance.

(1-5) The second thickness T2 is 50 nm or greater and 150 nm or less. This structure effectively mitigates electric field concentration at the end of the drain-side extension 36.

(1-6) The first thickness T1 is greater than the thickness of the drain-side extension 36. The first thickness T1, which is greater than the thickness of the drain-side extension 36, effectively reduces the source-gate capacitance.

(1-7) The total thickness of the first thickness T1 and the thickness of the drain-side extension 36 is greater than the thickness of the gate layer main body 32 and less than the total thickness of the thickness of the gate layer main body 32 and the thickness of the gate electrode 40. This structure further effectively reduces the source-gate capacitance.

(1-8) The passivation layer 50 includes the third part 55A, which is formed on the source-side extension 34 and has the third thickness T3, and the fourth part 55B, which is formed on the electron supply layer 28 and has the fourth thickness T4. The passivation layer 50 is formed so that the third thickness T3 of the third part 55A is greater than the fourth thickness T4 of the fourth part 55B. This structure reduces the source-gate capacitance and effectively mitigates electric field concentration at the end of the source-side extension 34.

(1-9) The ratio of the third thickness T3 to the fourth thickness T4 is greater than 1 and less than or equal to 3. This structure reduces the source-gate capacitance and further effectively mitigates electric field concentration at the end of the source-side extension 34.

(1-10) Further, the third part 55A is dominated by the region having the third thickness T3, and the fourth part 55B is dominated by the region having the fourth thickness T4. This structure reduces the source-gate capacitance and further effectively mitigates electric field concentration at the end of the source-side extension 34.

(1-11) The third thickness T3 is 100 nm or greater and 200 nm or less. This structure effectively reduces the source-gate capacitance.

(1-12) The fourth thickness T4 is 50 nm or greater and 150 nm or less. This structure effectively mitigates electric field concentration at the end of the source-side extension 34.

(1-13) The third thickness T3 is greater than the thickness of the source-side extension 34. The third thickness T3, which is greater than the thickness of the source-side extension 34, effectively reduces the source-gate capacitance.

(1-14) The total thickness of the third thickness T3 and the thickness of the source-side extension 34 is greater than the thickness of the gate layer main body 32 and less than the total thickness of the thickness of the gate layer main body 32 and the thickness of the gate electrode 40. This structure further effectively reduces the source-gate capacitance.

### Second Embodiment

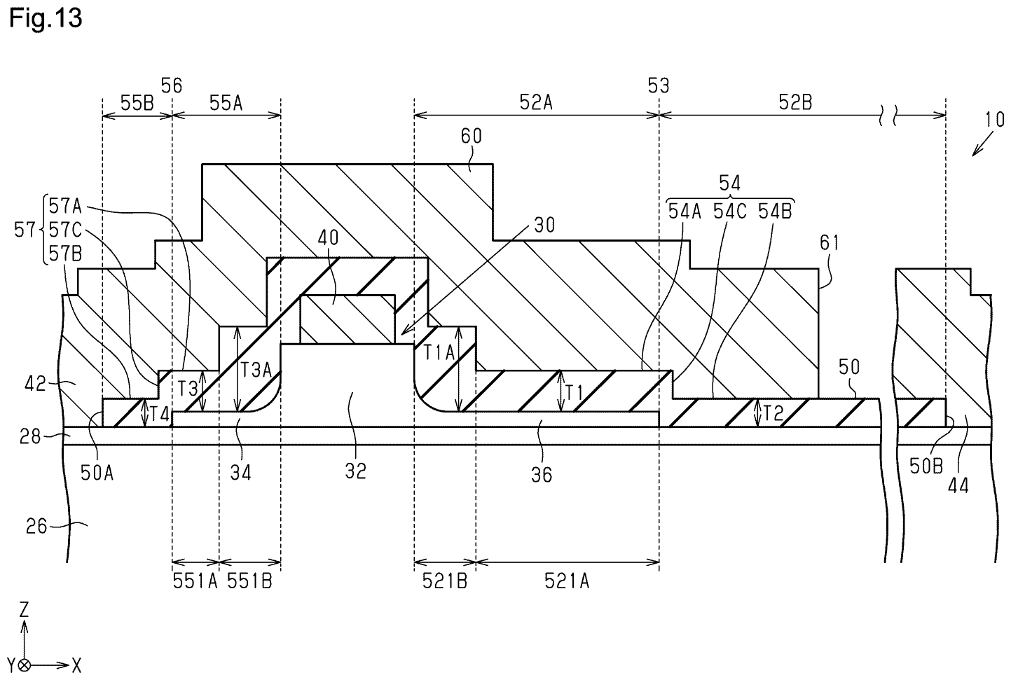

FIG. 13 is a schematic cross-sectional view of an exemplary nitride semiconductor device 10 in accordance with a second embodiment. The second embodiment differs from the first embodiment in that the thickness of the first part 52A and the thickness of the third part 55A are varied in the passivation layer 50. Otherwise, the structure is the same as the first embodiment. Thus, similar elements will not be described in detail.

As illustrated in FIG. 13, in the second embodiment, the first part 52A of the passivation layer 50 includes regions of different thicknesses. For example, the first part 52A includes a first region 521A, which has the first thickness T1, and a second region 521B, which is located closer to the gate layer main body 32 than the first region 521A and has a thickness TIA that is greater than the first thickness T1. More specifically, the first region 521A has a greater area than the second region 521B, in plan view. In the example of FIG. 13, the first part 52A is more dominated by the first region 521A than the second region 521B. The first thickness T1 of the first region 521A is also greater than the second thickness T2 of the second part 52B in this example.

In this structure, for example, the first thickness T1 of the first region 521A is less than that of the first embodiment. Thus, the effect for mitigating electric field concentration at the end of the drain-side extension 36 is more pronounced. Further, the first part 52A has regions with different thicknesses (first thickness T1 and thickness T1A). This allows the average thickness of the first part 52A to be increased. Thus, the gate-source capacitance can be decreased.

In the second embodiment, the boundary 53 of the first part 52A and the second part 52B is separated from the step wall 54C. In this manner, the boundary 53 does not have to be accurately aligned with the step wall 54C in plan view and may be separated slightly from the step wall 54C.

In the same manner, the third part 55A of the passivation layer 50 in the second embodiment includes regions of different thicknesses. For example, the third part 55A includes a third region 551A, which has the third thickness T3, and a fourth region 551B, which is located closer to the gate layer main body 32 than the third region 551A and has a thickness T3A that is greater than the third thickness T3. In the example of FIG. 13, the third part 55A is more dominated by the third region 551A than the fourth region 551B. More specifically, the third region 551A has a greater area than the fourth region 551B in plan view. The third thickness T3 of the third region 551A is greater than the fourth thickness T4 of the fourth part 55B.

In this structure, for example, the third thickness T3 of the third region 551A is less than that of the first embodiment. Thus, the effect for mitigating electric field concentration at the end of the source-side extension 34 is more pronounced. Further, the third part 55A has regions with different thicknesses (third thickness T3 and thickness T3A). This allows the average thickness of the third part 55A to be increased. Thus, the gate-source capacitance can be decreased.

In the second embodiment, the boundary 56 of the third part 55A is separated from the step wall 57C. In this manner, the boundary 56 does not have to be accurately aligned with the step wall 54C in plan view and may be separated slightly from the step wall 54C.

In addition to the advantages of the first embodiment, the nitride semiconductor device 10 has the advantages described below.

(2-1) The first part 52A has regions with different thicknesses (first thickness T1 and thickness TIA). This allows the average thickness of the first part 52A to be increased and allows the gate-source capacitance to be reduced. In addition, the first thickness T1 of the first region 521A is less than that of the first embodiment. Thus, the effect of mitigating electric field concentration at the end of the drain-side extension 36 is more pronounced.

(2-2) The third part 55A has regions with different thicknesses (third thickness T3 and thickness T3A). This allows the average thickness of the third part 55A to be increased and allows the gate-source capacitance to be reduced. In addition, the third thickness T3 of the third region 551A is less than that of the first embodiment. Thus, the effect for mitigating electric field concentration at the end of the source-side extension 34 is more pronounced.

### Third Embodiment

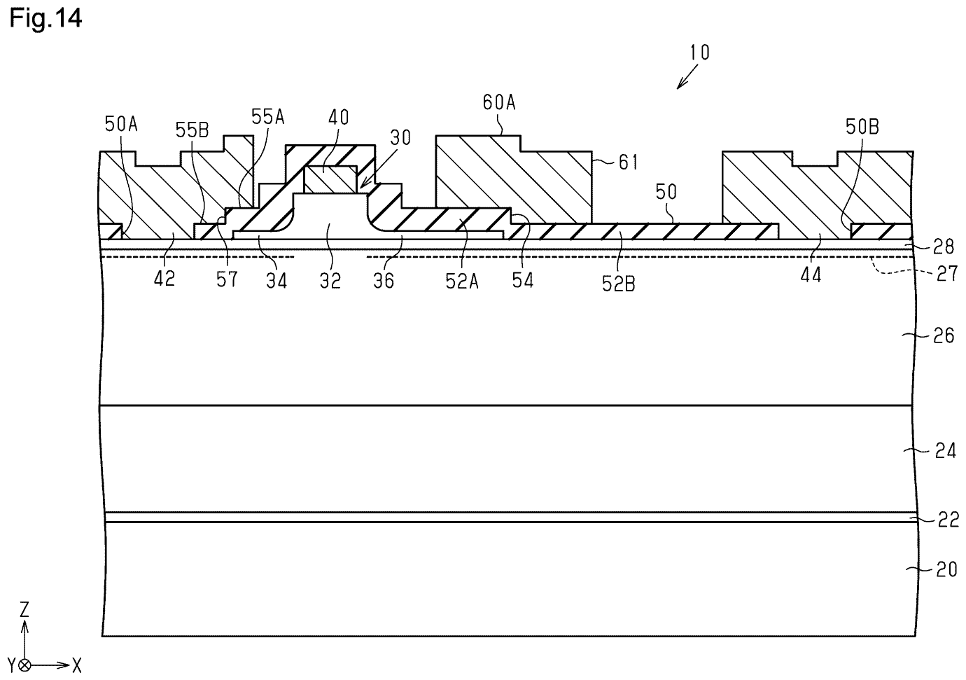

FIG. 14 is a schematic cross-sectional view of an exemplary nitride semiconductor device 10 in accordance with a third embodiment. The third embodiment differs from the second embodiment in that the field plate electrode 60 of the second embodiment is replaced by a field plate electrode 60A. Otherwise, the structure is the same as the first embodiment and the second embodiment. Thus, similar elements will not be described in detail.

As illustrated in FIG. 14, in the third embodiment, the field plate electrode 60A is separate from the source electrode 42. Although not illustrated in the drawing, the field plate electrode 60A is electrically connected to the source electrode 42. The field plate electrode 60A extends over the first part 52A, the first step 54, and the second part 52B to cover at least part (the end) of the drain-side extension 36 in plan view. In the example of FIG. 14, the field plate electrode 60A overlaps part of the drain-side extension 36 in plan view but does not overlap the entire drain-side extension 36. This structure decreases the region where the field plate electrode 60A overlaps the drain-side extension 36 in plan view and reduces the gate-source capacitance.

Further, the source electrode 42 extends over the third part 55A, the second step 57, and the fourth part 55B to cover at least part (the end) of the source-side extension 34 in plan view. In the example of FIG. 14, the source electrode 42 overlaps part of the source-side extension 34 in plan view but does not overlap the entire source-side extension 34. This structure decreases the region where the source electrode 42 overlaps the source-side extension 34 in plan view and reduces the gate-source capacitance.

In addition to the advantages of the first and second embodiments, the nitride semiconductor device 10 has the advantage described below.

(3-1) The region where the field plate electrode 60A overlaps the drain-side extension 36 in plan view is small. Further, the region where the source electrode 42 overlaps the source-side extension 34 in plan view is small. This reduces the gate-source capacitance.

### Modified Examples

The above embodiments may be modified as described below. The above-described embodiments and the modified examples described below may be combined as long as there is no technical contradiction.

The gate layer 30 does not have to be structured to include both the source-side extension 34 and the drain-side extension 36. For example, the gate layer 30 may be structured to include the gate layer main body 32 and the drain-side extension 36 but not the source-side extension 34.

In the first embodiment, the boundary 53 does not have to be accurately aligned with the step wall 54C in plan view and may be separated slightly from the step wall 54C like in the second and third embodiments. In the same manner, the boundary 56 does not have to be accurately aligned with the step wall 57C in plan view and may be separated slightly from the step wall 57C like in the second and third embodiments.

The first thickness T1 does not have to be greater than the thickness of the drain-side extension 36 and may be equal to the thickness of the drain-side extension 36. Further, the third thickness T3 does not have to be greater than the thickness of the source-side extension 34 and may be equal to the thickness of the source-side extension 34.

The total thickness of the first thickness T1 and the thickness of the drain-side extension 36 may be less than the thickness of the gate layer main body 32. Further, the total thickness of the third thickness T3 and the thickness of the source-side extension 34 may be less than the thickness of the gate layer main body 32.

In this specification, the word “on” includes the meaning of “above” in addition to the meaning of “on” unless otherwise described in the context. Accordingly, for example, the expression of “first element mounted in second element” may mean that the first element is placed directly on the second element in one embodiment and mean that the first element is placed above the second element without contacting the second element in another embodiment. Thus, the word “on” will also allow for a structure in which another element is formed between the first element and the second element.

The Z-axis direction as referred to in this specification does not necessarily have to be the vertical direction and does not necessarily have to fully coincide with the vertical direction. Accordingly, in the structures of the present disclosure, “up” and “down” in the Z-axis direction as referred to in this specification are not limited to “up” and “down” in the vertical direction. For example, the X-axis direction may be the vertical direction. Alternatively, the Y-axis direction may be the vertical direction.

### CLAUSES

Technical concepts that can be understood from each of the above embodiments and modified examples will now be described. The reference characters used to denote elements of the embodiments are illustrated in parenthesis for the corresponding elements of the clauses described below. The reference characters are given as examples to aid understanding and not intended to limit elements to the elements denoted by the reference characters.

### [Clause 1]

A nitride semiconductor device (10), including:
an electron transit layer (26) formed from a first nitride semiconductor;
an electron supply layer (28) arranged on the electron transit layer (26) and formed from a second nitride semiconductor having a bandgap that is larger than that of the first nitride semiconductor;
a gate layer (30) arranged on part of the electron supply layer (28) and formed from a third nitride semiconductor;
a gate electrode (40) arranged on the gate layer (30);
a passivation layer (50) covering the electron supply layer (28), the gate layer (30), and the gate electrode (40), and including a source opening (50A) and a drain opening (50B);
a source electrode (42) contacting the electron supply layer (28) through the source opening (50A);
a drain electrode (44) contacting the electron supply layer (28) through the drain opening (50B); and
a field plate electrode (60; 60A) arranged on the passivation layer (50) and electrically connected to the source electrode (42), where
the gate layer (30) includes a gate layer main body (32) and a drain-side extension (36) extending from the gate layer main body (32) toward the drain opening (50B),
the passivation layer (50) includes
   a first part (52A) overlapping both the drain-side extension (36) and the field plate electrode (60; 60A) in plan view,
   a second part (52B) continuous with the first part (52A) and located between the drain-side extension (36) and the drain opening (50B), and
   a first step (54) located in a region including a boundary (53) of the first part (52A) and the second part (52B),
the first step (54) includes an upper step surface (54A), a lower step surface (54B) that is lower than the upper step surface (54A), and a step wall (54C) that connects the upper step surface (54A) and the lower step surface (54B),
the first part (52A) has a first thickness (T1) from the upper step surface (54A) to an upper surface of the drain-side extension (36),
the second part (52B) has a second thickness (T2) from the lower step surface (54B) to an upper surface of the electron supply layer (28), and
the first thickness (T1) is greater than the second thickness (T2).

### [Clause 2]

The nitride semiconductor device (10) according to clause 1, where a ratio of the first thickness (T1) to the second thickness (T2) is greater than 1 and less than or equal to 3.

### [Clause 3]

The nitride semiconductor device (10) according to clause 1 or 2, where the first part (52A) is dominated by a region having the first thickness (T1), and the second part (52B) is dominated by a region having the second thickness (T2).

### [Clause 4]

The nitride semiconductor device (10) according to any one of clauses 1 to 3, where the first thickness (T1) is greater than or equal to 100 nm and less than or equal to 200 nm.

### [Clause 5]

The nitride semiconductor device (10) according to any one of clauses 1 to 4, where the second thickness (T2) is greater than or equal to 50 nm and less than or equal to 150 nm.

### [Clause 6]

The nitride semiconductor device (10) according to any one of clauses 1 to 5, where the first part (52A) includes a first region (521A) having the first thickness (T1), and a second region (521B) located closer to the gate layer main body (32) than the first region (521A) and having a thickness (T1A) that is greater than the first thickness (T1).

### [Clause 7]

The nitride semiconductor device (10) according to clause 6, where the first region (521A) has an area that is greater than that of the second region (521B) in plan view.

### [Clause 8]

The nitride semiconductor device (10) according to any one of clauses 1 to 7, where the first thickness (T1) is greater than a thickness of the drain-side extension (36).

### [Clause 9]

The nitride semiconductor device (10) according to any one of clauses 1 to 8, where a total thickness of the first thickness (T1) and a thickness of the drain-side extension (36) is greater than a thickness of the gate layer main body (32) and less than a total thickness of the thickness of the gate layer main body (32) and a thickness of the gate electrode (40).

### [Clause 10]

The nitride semiconductor device (10) according to any one of clauses 1 to 9, where
the gate layer (30) further includes a source-side extension (34) extending from the gate layer main body (32) toward the source opening (50A),
the passivation layer (50) includes
   a third part (55A) overlapping both the source-side extension (34) and the field plate electrode (60; 60A) in plan view,
   a fourth part (55B) continuous with the third part (55A) and located between the source-side extension (34) and the source opening (50A), and
   a second step (57) located in a region including a boundary (56) of the third part (55A) and the fourth part (55B),
the second step (57) includes an upper step surface (57A), a lower step surface (57B) that is lower than the upper step surface (57A) of the second step (57), and a step wall (57C) that connects the upper step surface (57A) and the lower step surface (57B) of the second step (57),
the third part (55A) has a third thickness (T3) from the upper step surface (57A) of the second step (57) to an upper surface of the source-side extension (34),
the fourth part (55B) has a fourth thickness (T4) from the lower step surface (57B) of the second step (57) to the upper surface of the electron supply layer (28), and
the third thickness (T3) is greater than the fourth thickness (T4).

### [Clause 11]

The nitride semiconductor device (10) according to clause 10, where a ratio of the third thickness (T3) to the fourth thickness (T4) is greater than 1 and less than or equal to 3.

### [Clause 12]

The nitride semiconductor device (10) according to clause 10 or 11, where the third thickness (T3) is greater than or equal to 100 nm and less than or equal to 200 nm.

### [Clause 13]

The nitride semiconductor device (10) according to any one of clauses 10 to 12, where the fourth thickness (T4) is greater than or equal to 50 nm and less than or equal to 150 nm.

### [Clause 14]

The nitride semiconductor device (10) according to any one of clauses 10 to 13, where the third part (55A) includes a third region (551A) having the third thickness (T3), and a fourth region (551B) located closer to the gate layer main body (32) than the third region (551A) and having a thickness (T3A) that is greater than the third thickness (T3).

### [Clause 15]

The nitride semiconductor device (10) according to any one of clauses 10 to 14, where the third thickness (T3) is greater than a thickness of the source-side extension (34).

### [Clause 16]

The nitride semiconductor device (10) according to any one of clauses 10 to 15, where a total thickness of the third thickness (T3) and a thickness of the source-side extension (34) is greater than a thickness of the gate layer main body (32) and less than a total thickness of the thickness of the gate layer main body (32) and a thickness of the gate electrode (40).

### [Clause 17]

The nitride semiconductor device according (10) to any one of clauses 1 to 16, where the field plate electrode (60) is formed integrally with the source electrode (42) and extends from the source electrode (42) toward the drain electrode (44) to cover the source-side extension (34), the gate layer main body (32), and the drain-side extension (36) in plan view.

### [Clause 18]

The nitride semiconductor device (10) according to any one of clauses 1 to 16, where the field plate electrode (60A) is separate from the source electrode (42) and extends over the first part (52A), the first step (54), and the second part (52B) to cover at least part of the drain-side extension (36) in plan view.

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in the disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer formed from a first nitride semiconductor;
an electron supply layer arranged on the electron transit layer and formed from a second nitride semiconductor having a bandgap that is larger than that of the first nitride semiconductor;
a gate layer arranged on part of the electron supply layer and formed from a third nitride semiconductor;
a gate electrode arranged on the gate layer;
a passivation layer covering the electron supply layer, the gate layer, and the gate electrode, and including a source opening and a drain opening;
a source electrode contacting the electron supply layer through the source opening;
a drain electrode contacting the electron supply layer through the drain opening; and
a field plate electrode arranged on the passivation layer and electrically connected to the source electrode, wherein
the gate layer includes a gate layer main body and a drain-side extension extending from the gate layer main body toward the drain opening,
the passivation layer includes
a first part overlapping both the drain-side extension and the field plate electrode in plan view,
a second part continuous with the first part and located between the drain-side extension and the drain opening, and
a first step located in a region including a boundary of the first part and the second part,
the first step includes an upper step surface, a lower step surface that is lower than the upper step surface, and a step wall that connects the upper step surface and the lower step surface,
the first part has a first thickness from the upper step surface to an upper surface of the drain-side extension,
the second part has a second thickness from the lower step surface to an upper surface of the electron supply layer, and
the first thickness is greater than the second thickness.

2. The nitride semiconductor device according to claim 1, wherein a ratio of the first thickness to the second thickness is greater than 1 and less than or equal to 3.

3. The nitride semiconductor device according to claim 1, wherein
the first part is dominated by a region having the first thickness, and
the second part is dominated by a region having the second thickness.

4. The nitride semiconductor device according to claim 1, wherein the first thickness is greater than or equal to 100 nm and less than or equal to 200 nm.

5. The nitride semiconductor device according to claim 1, wherein the second thickness is greater than or equal to 50 nm and less than or equal to 150 nm.

6. The nitride semiconductor device according to claim 1, wherein the first part includes
a first region having the first thickness, and
a second region located closer to the gate layer main body than the first region and having a thickness that is greater than the first thickness.

7. The nitride semiconductor device according to claim 6, wherein the first region has an area that is greater than that of the second region in plan view.

8. The nitride semiconductor device according to claim 1, wherein the first thickness is greater than a thickness of the drain-side extension.

9. The nitride semiconductor device according to claim 1, wherein a total thickness of the first thickness and a thickness of the drain-side extension is greater than a thickness of the gate layer main body and less than a total thickness of the thickness of the gate layer main body and a thickness of the gate electrode.

10. The nitride semiconductor device according to claim 1, wherein
the gate layer further includes a source-side extension extending from the gate layer main body toward the source opening,
the passivation layer includes
a third part overlapping both the source-side extension and the field plate electrode in plan view,
a fourth part continuous with the third part and located between the source-side extension and the source opening, and
a second step located in a region including a boundary of the third part and the fourth part,
the second step includes an upper step surface, a lower step surface that is lower than the upper step surface of the second step, and a step wall that connects the upper step surface and the lower step surface of the second step,
the third part has a third thickness from the upper step surface of the second step to an upper surface of the source-side extension,
the fourth part has a fourth thickness from the lower step surface of the second step to the upper surface of the electron supply layer, and
the third thickness is greater than the fourth thickness.

11. The nitride semiconductor device according to claim 10, wherein a ratio of the third thickness to the fourth thickness is greater than 1 and less than or equal to 3.

12. The nitride semiconductor device according to claim 10, wherein the third thickness is greater than or equal to 100 nm and less than or equal to 200 nm.

13. The nitride semiconductor device according to claim 10, wherein the fourth thickness is greater than or equal to 50 nm and less than or equal to 150 nm.

14. The nitride semiconductor device according to claim 10, wherein the third part includes
a third region having the third thickness, and
a fourth region located closer to the gate layer main body than the third region and having a thickness that is greater than the third thickness.

15. The nitride semiconductor device according to claim 10, wherein the third thickness is greater than a thickness of the source-side extension.

16. The nitride semiconductor device according to claim 10, wherein a total thickness of the third thickness and a thickness of the source-side extension is greater than a thickness of the gate layer main body and less than a total thickness of the thickness of the gate layer main body and a thickness of the gate electrode.

17. The nitride semiconductor device according to claim 1, wherein the field plate electrode is formed integrally with the source electrode and extends from the source electrode toward the drain electrode to cover the gate layer main body and the drain-side extension in plan view.

18. The nitride semiconductor device according to claim 1, where the field plate electrode is separate from the source electrode and extends over the first part, the first step, and the second part to cover at least part of the drain-side extension in plan view.
